(19) United States
(12) Patent Application Publication
(10) Pub. No.: US 2025/0183235 A1
(43) Pub. Date: Jun. 5, 2025

(54) METHOD OF MANUFACTURING DISPLAY DEVICE AND DISPLAY DEVICE

(71) Applicant: Samsung Display Co., LTD., Yongin-si (KR)

(72) Inventor: Jeong Won HAN, Yongin-si (KR)

(73) Assignee: Samsung Display Co., LTD., Yongin-si (KR)

(21) Appl. No.: 18/762,142

(22) Filed: Jul. 2, 2024

(30) Foreign Application Priority Data
Dec. 4, 2023 (KR) 10-2023-0173803

(51) Int. Cl. H01L 25/075; H01L 33/62

(52) U.S. Cl. CPC H01L 25/0753; H10H 20/857; H10H 20/0364

(57) ABSTRACT

There are provided a method of manufacturing a display device and a display device. The method includes manufacturing light emitting elements; disposing the light emitting elements on a moving member; bonding the light emitting elements and a stamp member to each other; and transferring the light emitting elements on a pixel circuit layer. The moving member includes a moving base and a moving polymer layer on the moving base. The disposing of the light emitting elements includes attaching the light emitting elements on the moving polymer layer. The bonding of the light emitting elements includes separating the light emitting elements and the moving polymer layer from each other, by a laser.

### CROSS-REFERENCE TO RELATED APPLICATION(S)

This application claims priority to and benefits of Korean Patent Application No. 10-2023-0173803 under 35 U.S.C. § 119, filed on Dec. 4, 2023 in the Korean Intellectual Property Office, the entire contents of which are incorporated herein by reference.

### BACKGROUND

### 1. Technical Field

The disclosure generally relates to a method of manufacturing a display device and a display device.

### 2. Description of the Related Art

Recently, as interest in information displays is increased, research and development of display devices have been continuously conducted. A display device may include a light emitting element as a light source. The light emitting element may be transferred on a substrate for manufacturing the display device by various methods.

For example, the light emitting element may be transferred on a backplane of the display device, using a stamp film including at least one layer. The stamp film may be attached to the light emitting element, using adhesion defined at a portion of the stamp film, and the light emitting element adhered on the stamp film may be moved on the backplane.

However, the adhesion between the stamp film and the light emitting element may have difficulty in being uniformly defined for each area due to a material characteristic variation for each position of the stamp film. A risk that the light emitting element will not be transferred in a partial area on the backplane may occur.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a method of manufacturing a display device and a display device, in which the transfer stability of a light emitting element is ensured and process precision is improved, so that a risk that the light emitting element will not be transferred can be reduced, and the defect rate of the display device can be decreased.

In accordance with an aspect of the disclosure, there is provided a method of manufacturing a display device, the method may include manufacturing light emitting elements; disposing the light emitting elements on a moving member; bonding the light emitting elements and a stamp member to each other; and transferring the light emitting elements on a pixel circuit layer, wherein the moving member may include a moving base and a moving polymer layer on the moving base, wherein the disposing of the light emitting elements may include attaching the light emitting elements on the moving polymer layer, and wherein the bonding of the light emitting elements may include separating the light emitting elements and the moving polymer layer from each other, by a laser.

The manufacturing of the light emitting elements may include manufacturing a first light emitting element that emits light of a first color; manufacturing a second light emitting element that emits light of a second color; and manufacturing a third light emitting element that emits light of a third color.

The first light emitting element, the second light emitting element, and the third light emitting element may be respectively manufactured on separate growth substrates. The manufacturing of the first light emitting element, the manufacturing of the second light emitting element, and the manufacturing of the third light emitting element may be sequentially performed.

The disposing of the light emitting elements may include causing the moving polymer layer and the light emitting elements to contact each other.

The moving polymer layer may include at least one selected from the group consisting of epoxy resin, phenol resin, polyimide resin, polyurethane resin, melamine resin, and urea resin.

The stamp member may include a stamp base and a stamp layer disposed on the stamp base. The bonding of the light emitting elements may include the stamp layer and at least some of the light emitting elements to contact each other.

The stamp layer may include a plurality of protrusion portions spaced apart from each other. The bonding of the light emitting elements may include bonding the light emitting elements respectively to the plurality of protrusion portions.

The separating of the light emitting elements may include applying the laser to at least a portion of the moving polymer layer; and decreasing an adhesion between the at least a portion of the moving polymer layer, to which the laser is applied, and the light emitting elements.

In the separating of the light emitting elements, the adhesion between the at least a portion of the moving polymer layer and the light emitting elements after the laser is applied may be less than an adhesion between the stamp layer and the light emitting elements.

The laser may have an ultraviolet wavelength band.

The laser may have a wavelength in a range of about 245 nm to about 350 nm.

The transferring of the light emitting elements may include disposing the light emitting elements on the pixel circuit layer by performing a laser bonding process, a thermo-compression bonding process, or a eutectic bonding process.

Each of the light emitting elements may be a flip chip type micro light emitting element (LED), a lateral type micro LED, or a vertical type micro LED.

In accordance with another aspect of the disclosure, there is provided a display device manufactured according the method.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device in accordance with an embodiment.

FIG. 2 is an example view illustrating an example of a pixel shown in FIG. 1.

FIG. 3 is a schematic sectional view illustrating an example of the display device.

FIG. 4 is a flowchart illustrating a method of manufacturing a display device in accordance with an embodiment.

FIGS. 5 to 13 are schematic sectional views illustrating process steps of the method of manufacturing the display device in accordance with an embodiment.

### DETAILED DESCRIPTION OF THE EMBODIMENTS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

An expression that an element such as a layer, region, substrate or plate is placed “on” or “above” another element indicates not only a case where the element is placed “directly on” or “just above” the other element but also a case where a further element is disposed between the element and the other element. On the contrary, an expression that an element such as a layer, region, substrate or plate is placed “beneath” or “below” another element indicates not only a case where the element is placed “directly beneath” or “just below” the other element but also a case where a further element is disposed between the element and the other element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

The disclosure generally relates to a method of manufacturing a display device and a display device. Hereinafter, a method of manufacturing a display device and a display device in accordance with an embodiment of the disclosure will be described with reference to the accompanying drawings.

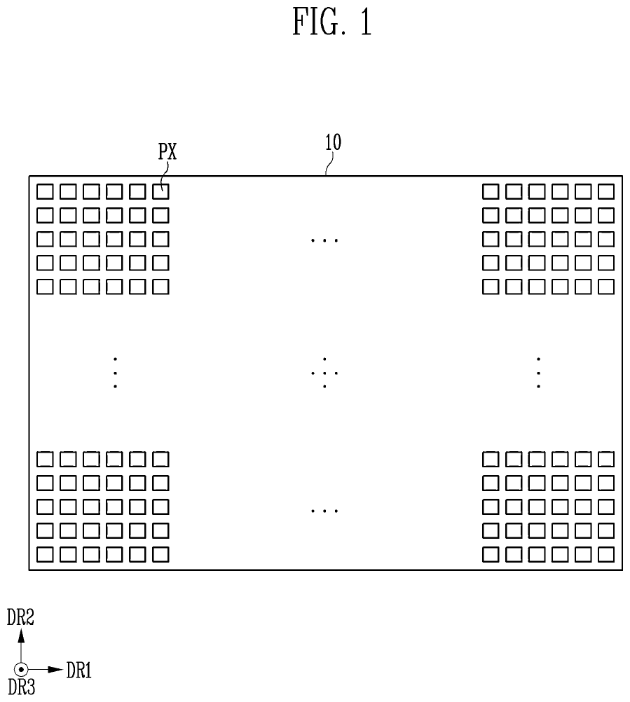

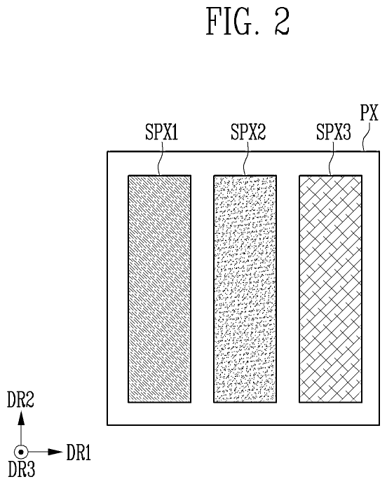

FIG. 1 is a schematic plan view illustrating a display device in accordance with an embodiment. FIG. 2 is an example view illustrating an example of a pixel shown in FIG. 1.

Referring to FIG. 1, the display device 10 is that outputs optical information. For example, the display device 10 is a device which displays a moving image or a still image, and may be used as a display screen of not only portable electronic devices such as a mobile phone, a smart phone, a tablet personal computer (PC), a mobile communication terminal, an electronic notebook, an electronic book, a portable multimedia player (PMP), a navigation system, and an ultra-mobile PC, but also various products such as a television, a notebook computer, a monitor, an advertisement board, and Internet of things (IoT).

The display device 10 may be formed in a rectangular plane having long sides in a first direction DR1 and short sides in a second direction DR2 intersecting the first direction DR1. A corner at which the long side in the first direction DR1 and the short side in the second direction DR2 meet each other may be formed round to have a selectable curvature or be formed at a right angle. The planar shape of the display device 10 is not limited to a quadrangular shape, and the display device 10 may be formed in another polygonal shape, a circular shape, or an elliptical shape or substantially similar shape. The display device 10 may be formed flat, but the disclosure is not limited thereto. For example, the display device 10 may include a curved portion which is formed at a left/right end and has a constant curvature or a changing curvature. In addition, the display device 10 may be formed flexible enough to be warpable, curvable, bendable, foldable or rollable.

The display device 10 may further include pixels PX for displaying an image, scan lines extending in the first direction DR1, and data lines extending in the second direction DR2. The pixels PX may be arranged (or disposed) in a matrix form in the first direction DR1 and the second direction DR2.

Each of the pixels PX may include a plurality of sub-pixels SPX1, SPX2, and SPX3 as shown in FIG. 2. In FIG. 2, it is described that each of the pixels PX may include three sub-pixels SPX1, SPX2, and SPX3, for example, a first sub-pixel SPX1, a second sub-pixel SPX2, and a third sub-pixel SPX3. However, the embodiment of the disclosure is not limited thereto.

The first sub-pixel SPX1, the second sub-pixel SPX2, and the third sub-pixel SPX3 may be connected to any one data line among the data lines and at least one scan line among the scan lines.

Each of the first sub-pixel SPX1, the second sub-pixel SPX2, and the third sub-pixel SPX3 may have a rectangular, square or rhombic planar shape. For example, each of the first sub-pixel SPX1, the second sub-pixel SPX2, and the third sub-pixel SPX3 may have a rectangular planar shape having short sides in the first direction DR1 and long sides in the second direction DR2 as shown in FIG. 2. By way of example, in an embodiment, each of the first sub-pixel SPX1, the second sub-pixel SPX2, and the third sub-pixel SPX3 may have a square or rhombic planar shape including sides having the same length in the first direction DR1 and the second direction DR2.

As shown in FIG. 2, the first sub-pixel SPX1, the second sub-pixel SPX2, and the third sub-pixel SPX3 may be arranged in the first direction DR1. By way of example, any one of the second sub-pixel SPX2 and the third sub-pixel SPX3 and the first sub-pixel SPX1 may be arranged in the first direction DR1, and the other of the second sub-pixel SPX2 and the third sub-pixel SPX3 and the first sub-pixel SPX1 may be arranged in the second direction DR2.

By way of example, any one of the first sub-pixel SPX1 and the third sub-pixel SPX3 and the second sub-pixel SPX2 may be arranged in the first direction DR1, and the other of the first sub-pixel SPX1 and the third sub-pixel SPX3 and the second sub-pixel SPX2 may be arranged in the second direction DR2. By way of example, any one of the first sub-pixel SPX1 and the second sub-pixel SPX2 and the third sub-pixel SPX3 may be arranged in the first direction DR1, and the other of the first sub-pixel SPX1 and the second sub-pixel SPX2 and the third sub-pixel SPX3 may be arranged in the second direction DR2.

The first sub-pixel SPX1 may emit first light, the second sub-pixel SPX2 may emit second light, and the third sub-pixel SPX3 may emit third light. The first light may be light in a red wavelength band, the second light may be light in a green wavelength band, and the third light may be light in a blue wavelength band. The red wavelength band may be a wavelength band of in a range of about 600 nm to about 750 nm, the green wavelength band may be a wavelength band of in a range of about 480 nm to about 560 nm, and the blue wavelength band may be a wavelength band in a range of about 370 nm to about 460 nm. However, the embodiment of the disclosure is not limited thereto.

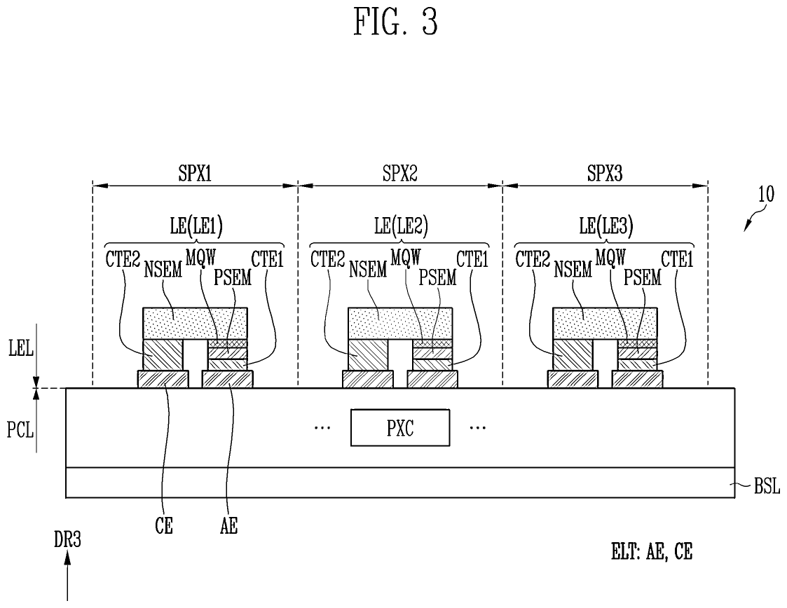

Each of the first sub-pixel SPX1, the second sub-pixel SPX2, and the third sub-pixel SPX3 may include an inorganic light emitting element having an inorganic semiconductor as a light emitting element LE (see FIG. 3) emitting light.

In an embodiment, the light emitting element LE may have various shapes. For example, the light emitting element LE may be a flip chip type micro light emitting diode (LED). By way of example, the light emitting element LE may be a lateral type micro LED. By way of example, the light emitting element LE may be a vertical type micro LED. However, an embodiment is not limited to a specific example.

As shown in FIG. 2, an area of the first sub-pixel SPX1, an area of the second sub-pixel SPX2, and an area of the third sub-pixel SPX3 may be substantially the same, but an embodiment is not limited thereto. At least one of the area of the first sub-pixel SPX1, the area of the second sub-pixel SPX2, and the area of the third sub-pixel SPX3 may be different from another of the area of the first sub-pixel SPX1, the area of the second sub-pixel SPX2, and the area of the third sub-pixel SPX3. By way of example, any two of the area of the first sub-pixel SPX1, the area of the second sub-pixel SPX2, and the area of the third sub-pixel SPX3 may be substantially the same, and the other of area of the first sub-pixel SPX1, the area of the second sub-pixel SPX2, and the area of the third sub-pixel SPX3 may be different from the two of the area of the first sub-pixel SPX1, the area of the second sub-pixel SPX2, and the area of the third sub-pixel SPX3. By way of example, the area of the first sub-pixel SPX1, the area of the second sub-pixel SPX2, and the area of the third sub-pixel SPX3 may be different from one another.

FIG. 3 is a sectional view illustrating an example of the display device.

Referring to FIG. 3, the display device 10 may include a pixel circuit layer PCL and a light emitting element layer LEL.

The pixel circuit layer PCL may be a layer including pixel circuits PXC for driving light emitting elements LE. The pixel circuit layer PCL may be a backplane layer. The pixel circuit layer PCL may include a base layer BSL, metal layers for forming the pixel circuits PXC, and insulating layers disposed between the metal layers. In an embodiment, the base layer BSL may be a base substrate or a base member, which is used to support the display device 10. The base layer BSL may be a rigid substrate made of a glass material. The base layer BSL may include a silicon material. The base layer BSL may be a flexible substrate which is bendable, foldable, rollable, and the like within the spirit and the scope of the disclosure. The base layer BSL may include an insulating material including polymer resin such as polyimide. In an embodiment, each of the pixel circuits PXC may include a transistor. For example, each of the pixel circuits PXC may include a thin film transistor. Each of the pixel circuits PXC may further include a storage capacitor. The pixel circuits PXC may be electrically connected to the light emitting elements LE, to provide an electrical signal for allowing the light emitting elements LE to emit light.

The light emitting element layer LEL may be disposed on the pixel circuit layer PCL. The light emitting element layer LEL may include an electrode layer ELT and the light emitting elements LE. The electrode layer ELT may include pixel electrodes AE and common electrodes CE.

Each of a first sub-pixel SPX1, a second sub-pixel SPX2, and a third sub-pixel SPX3 may include a light emitting element LE connected to a pixel electrode AE and a common electrode CE.

In an embodiment, the light emitting elements LE may include a first light emitting element LE1 included in the first sub-pixel SPX1, which emits light of a first color, a second light emitting element LE2 included in the second sub-pixel SPX2, that emits light of a second color, and a third light emitting element LE3 included in the third sub-pixel SPX3, that emits light of a third color. The pixel electrode AE may be designated as an anode electrode, and the common electrode CE may be designated as a cathode electrode.

The pixel electrodes AE and the common electrodes CE may be disposed on the pixel circuit layer PCL. Each of the pixel electrodes AE may be electrically connected to the pixel circuit PXC of the pixel circuit layer PCL. Accordingly, a pixel voltage or an anode voltage, which is controlled by the pixel circuit PXC (for example, the transistor), may be applied to the pixel electrode AE.

Each of the common electrodes CE may be electrically connected to a power line formed in the pixel circuit layer PCL. Accordingly, a power voltage of the power line may be applied to the common electrodes CE.

The pixel electrodes AE and the common electrode CE may include a metal material having a high reflectivity, such as a stacked structure (Ti/Al/Ti) of aluminum and titanium, a stacked structure (ITO/Al/ITO) of aluminum and ITO, an APC alloy, or a stacked structure (ITO/APC/ITO) of an APC alloy and ITO. The APC alloy may be an alloy of silver (Ag), palladium (Pd), and copper (Cu). However, the disclosure is not limited thereto.

In FIG. 3, it is described that each of the light emitting elements LE is a flip chip type micro LED in which a first contact electrode CTE1 and a second contact electrode CTE2 are disposed such that the pixel electrode AE and the common electrode CE face each other. However, the shape of the light emitting element LE is not necessarily limited thereto.

The light emitting element LE may include an inorganic material (for example, GaN). Each of a length of the light emitting element LE in the first direction DR1, a length of the light emitting element LE in the second direction DR2, and a length of the light emitting element LE in a third direction DR3 may be a few to hundreds of micrometers (μm). For example, each of the length of the light emitting element LE in the first direction DR1, the length of the light emitting element LE in the second direction DR2, and the length of the light emitting element LE in the third direction DR3 may be about 100 μm or less. However, the disclosure is not limited thereto.

Each of the light emitting elements LE may be a light emitting structure including an n-type semiconductor NSEM, an active layer MQW, a p-type semiconductor PSEM, a first contact electrode CTE1, and a second electrode CTE2.

A portion of the n-type semiconductor NSEM may be disposed on the active layer MQW. A portion of the n-type semiconductor NSEM may be disposed on the second contact electrode CTE2. In an embodiment, a surface of the n-type semiconductor NSEM may face a display surface. The n-type semiconductor NSEM may be made of GaN doped with an n-type conductivity type dopant such as Si, Ge or Sn.

The active layer MQW may be disposed on a portion of one surface or a surface of the n-type semiconductor NSEM. The active layer MQW may be disposed between the n-type semiconductor NSEM and the p-type semiconductor PSEM. The active layer MQW may include a material having a single or multiple quantum well structure. In case that the active layer MQW may include the material having the multiple quantum well structure, the active layer MQW may have a structure in which a plurality of well layers and a plurality of barrier layers are alternately stacked each other. The well layer may be formed of InGaN, and the barrier layer may be formed of GaN or AlGaN. However, the disclosure is not limited thereto. By way of example, the active layer MQW may have a structure in which a semiconductor material having a high band gap energy and a semiconductor material having a low band gap energy are alternately stacked each other. The active layer MQW may include different Group III to V semiconductor materials according to a wavelength range of emitted light.

The p-type semiconductor PSEM may be disposed on a surface of the active layer MQW. The p-type semiconductor PSEM may be made of GaN doped with a p-type conductivity type dopant such as Mg, Zn, Ca, Se or Ba.

The first contact electrode CTE1 may be disposed on the p-type semiconductor PSEM, and the second contact electrode CTE2 may be disposed on another portion of a surface of the n-type semiconductor NSEM. The another portion of the surface of the n-type semiconductor NSEM, on which the second contact electrode CTE2 is disposed, may be disposed distant from the portion of the surface of the n-type semiconductor NSEM, on which the active layer MQW is disposed.

The first and second contact electrodes CTE1 and CTE2 and the electrode layer ELT may be adhered to each other, based on various methods. For example, the first and second contact electrodes CTE1 and CTE2 and the electrode layer ELT may be adhered to each other through a conductive adhesive member such as an Anisotropic Conductive Film (ACF) or an Anisotropic Conductive Paste (ACP). The first and second contact electrodes CTE1 and CTE2 and the electrode layer ELT may be adhered to each other through a laser bonding process or a thermo-compression bonding process. The first and second contact electrodes CTE1 and CTE2 and the electrode layer ELT may be adhered to each other through a soldering process. The first and second contact electrodes CTE1 and CTE2 and the electrode layer ELT may be adhered to each other through a eutectic bonding process.

In an embodiment, in case that the light emitting element LE is a flip chip type micro LED or a lateral type micro LED, a bump layer may be disposed on the electrode layer ELT, and the light emitting element LE may be attached to the electrode layer ELT through a laser bonding process or a thermo-compression bonding process. By way of example, in an embodiment, in case that the light emitting element LE is a vertical type micro LED, a low melting point material layer having a relatively low melting point may be disposed on the electrode layer ELT, and the light emitting element LE may be attached to the electrode layer ELT through a eutectic bonding process. However, the process of transferring the light emitting element LE in the disclosure is not particularly limited.

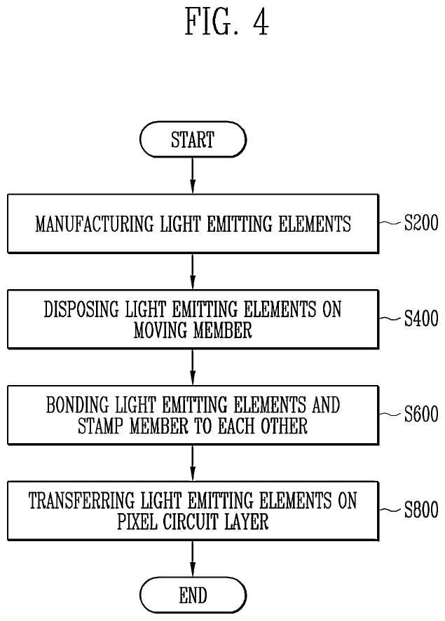

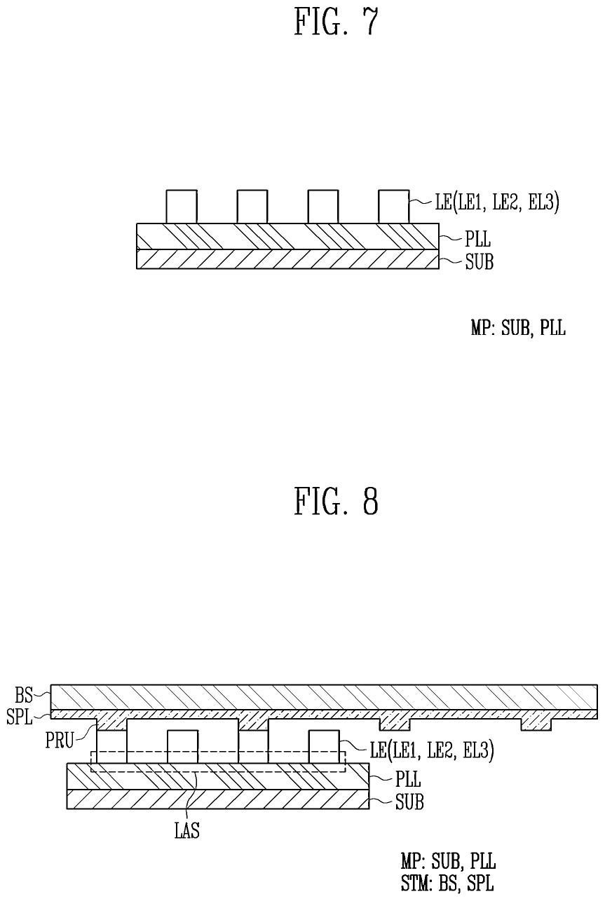

A method of manufacturing the display device 10 will be described with reference to FIGS. 4 to 13. In FIGS. 4 to 13, descriptions of portions overlapping those described above will be simplified or will not be repeated.

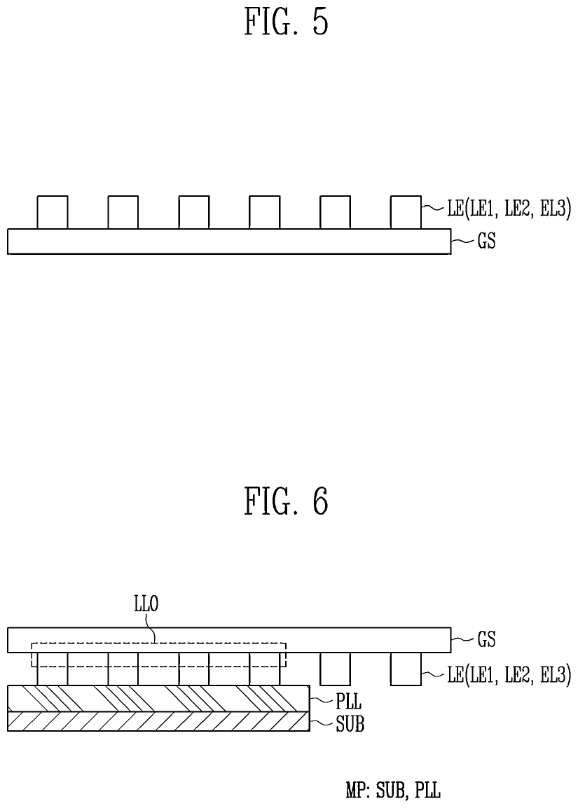

FIG. 4 is a flowchart illustrating a method of manufacturing a display device in accordance with an embodiment. FIGS. 5 to 13 are schematic sectional views illustrating process steps of the method of manufacturing the display device in accordance with an embodiment.

Referring to FIG. 4, the method of manufacturing the display device 10 in accordance with an embodiment may include step S200 of manufacturing light emitting elements, step S400 of disposing the light emitting elements on a moving member, step S600 of bonding the light emitting elements and a stamp member to each other, and step S800 of transferring the light emitting elements on a pixel circuit layer.

Referring to FIGS. 4 and 5, in the step S200 of manufacturing the light emitting elements, light emitting elements LE may be provided on a growth substrate GS.

In this step S200, after semiconductor layers are grown (for example, epitaxially grown) on the growth substrate GS (for example, a wafer), the light emitting elements LE may be manufactured by etching the semiconductor layers. In an embodiment, an electrode structure (for example, a first contact electrode CTE1 and a second contact electrode CTE2) may be further formed on the semiconductor layers.

In an embodiment, each of first to third light emitting elements LE1 to LE3 may be manufactured on a growth substrate GS. For example, in the display device 10 in accordance with an embodiment, the first to third light emitting elements LE1 to LE3 may emit light of different colors. Accordingly, the first light emitting element LE1 for emitting light of a first color may be manufactured on a growth substrate GS, the second light emitting element LE2 for emitting light of a second color may be manufactured on another growth substrate GS, and the third light emitting element LE3 for emitting light of a third color may be manufactured on another growth substrate GS. However, in an embodiment, the first to third light emitting elements LE1 to LE2 may be patterned in different areas on a growth substrate GS.

In the following steps, technical characteristics described with respect to the light emitting elements LE may be equally applied to process steps of each of the first to third light emitting elements LE1 to LE3. As described above, the first to third light emitting elements LE1 to LE3 may be individually manufactured. Therefore, for convenience of description, a method of manufacturing each of the first to third light emitting elements LE1 to LE3 will be described based on the light emitting elements LE.

Referring to FIGS. 4, 6, and 7, in the step S400 of disposing the light emitting elements on the moving member, at least some of the light emitting elements LE may be disposed on a surface of a moving member MP.

The moving member MP is a member on which the light emitting elements LE are temporarily disposed, and may move the light emitting elements LE from the growth substrate GS to a stamp member STM (see FIG. 8). For example, the moving member MP may be a carrier wafer. The moving member MP may be a donor plate. The moving member MP may be a receiver substrate.

The moving member MP may include a moving base SUB and a moving polymer layer PLL.

The moving base SUB may include a relatively rigid material, and form a base on which the moving polymer layer PLL is disposed.

The moving polymer layer PLL may be a layer including polymer. For example, the moving polymer layer PLL may include at least one selected from the group consisting of epoxy resin, phenol resin, polyimide resin, polyurethane resin, melamine resin, and urea resin. However, the disclosure is not limited thereto.

The moving polymer layer PLL may be a layer in contact with the light emitting element LE. For example, in this step S400, a portion of the light emitting element LE may be attached to the moving member MP (for example, the moving polymer layer PLL). For example, since the moving polymer layer PLL may include polymer, the moving polymer layer PLL may have an adhesive property with respect to the light emitting element LE. After the light emitting elements LE are attached to the moving polymer layer PLL, a laser lift-off (LLO) process may be performed between the growth substrate GS and the light emitting elements LE. Accordingly, the growth substrate GS and the light emitting elements GS may be separated from each other, and the light emitting elements LE may be disposed on the moving member MP.

In an embodiment, the light emitting elements LE disposed on the moving member MP may be again moved on another moving member MP which is separately provided such that the direction in which the light emitting elements LE are disposed on the moving member MP can be changed. In an embodiment, in case that each of the light emitting elements LE is a flip chip type micro LED, the light emitting elements LE may not be disposed on another separate moving member MP. In case that each of the light emitting elements LE is a lateral type micro LED, the light emitting elements LE may be another separate moving member MP. However, the disclosure is not limited thereto.

Referring to FIGS. 4 and 8, in the step S600 of bonding the light emitting elements and the stamp member to each other, the light emitting elements LE on the moving member MP may be attached to the stamp member STM.

In this step S600, a surface of each of the light emitting elements LE may face the moving polymer layer PLL, and the other surface of each of the light emitting elements LE may face the stamp member STM. The other surface of each of the light emitting elements LE may be attached to a portion of the stamp member STM.

In this step S600, although not shown in the drawing, the stamp member STM may be attached by a stamp head device, and the behavior of the stamp member STM may be controlled. In an embodiment, the stamp head device may fix a position of the stamp member STM, using a method using an electrostatic chuck, an adhesive chuck, a vacuum chuck, or a porous vacuum chuck, and move the position of the stamp member STM, using various methods.

In an embodiment, the stamp member STM may include a stamp base BS and a stamp layer SPL.

The stamp base BS may form a base on which the stamp layer SPL is disposed. In an embodiment, the movement of the stamp base BS may be controlled by the stamp head device.

The stamp base BS may include various rigid or flexible materials. For example, the stamp base BS may include polyethylene terephthalate (PET) or polycarboxylate ether (PCE). By way of example, the stamp base BS may include a glass material. For example, the stamp base BS may include Ultra Thin Glass (UTG). However, the disclosure is not limited thereto.

The stamp layer SPL may be disposed on the stamp base BS. The stamp layer SPL may form an area in which the light emitting element LE can be attached.

In an embodiment, the stamp layer SPL may include a protrusion portion PRU which can be bonded to each of the light emitting elements LE. For example, the protrusion portion PRU may include a plurality of protrusion portions PRU, each of which can be bonded to a light emitting element LE. The plurality of protrusion portions PRU may be spaced apart from each other. However, the disclosure is not necessarily limited thereto. For example, the stamp layer SPL may not include the protrusion portion PRU, and the light emitting elements LE may be attached on roughly flat surfaces of the stamp layer SPL.

The stamp layer SPL may include a relatively flexible material. For example, the stamp layer SPL may include polydimethylsiloxane (PDMS). However, the disclosure is not limited thereto.

In this step S600, the light emitting elements LE and the moving polymer layer PLL may be separated from each other, using laser LAS.

In accordance with an embodiment, in case that the laser LAS is applied to the moving polymer layer PLL, the adhesion of the moving polymer layer PLL may be decreased. In a state in which the adhesion between the light emitting elements LE and the moving polymer layer PLL is decreased as a laser LAS process is performed, the stamp layer SPL and the light emitting elements LE may be attached to each other by a relatively strong adhesion. Accordingly, the light emitting elements LE and the moving polymer layer PLL may be spaced apart from each other. For example, in case that the light emitting element LE is moved from the moving member MP to the stamp member STM, an adhesion between the light emitting element LE and the stamp layer SPL may be greater than an adhesion between the light emitting element LE and the moving polymer PLL.

In an embodiment, the laser LAS may have a wavelength band capable of decreasing the adhesion of the moving polymer layer PLL. For example, the laser LAS may have an ultraviolet wavelength band. The laser LAS may have a wavelength in a range of about 150 nm to about 400 nm. By way of example, the laser LAS may have a wavelength in a range of about 245 nm to about 350 nm. In case that a process using the laser LAS is performed, the light emitting elements LE can be stably provided on the stamp member STM without being excessively damaged, and the adhesion between the light emitting elements LE and the moving member MP can be thoroughly decreased using the laser LAS. Thus, a risk that the light emitting elements LE will not be transferred on a portion of the stamp layer SPL can be reduced. Consequently, a risk that the light emitting elements LE will not be finally transferred in a partial area on a pixel circuit layer PCL can be reduced, and accordingly, the defect rate of the display device 10 can be decreased.

However, the method of separating the moving polymer layer PLL and the light emitting elements LE from each other, using the laser LAS is not limited to the above-described example. In an embodiment, in case that the laser LAS is applied to the moving polymer layer PLL, at least a portion of the moving polymer layer PLL may be removed in an area in which the light emitting elements LE and the moving polymer layer PLL are adjacent to each other. Accordingly, the light emitting elements LE may be separated from the moving polymer layer PLL, and be disposed on the stamp member STM.

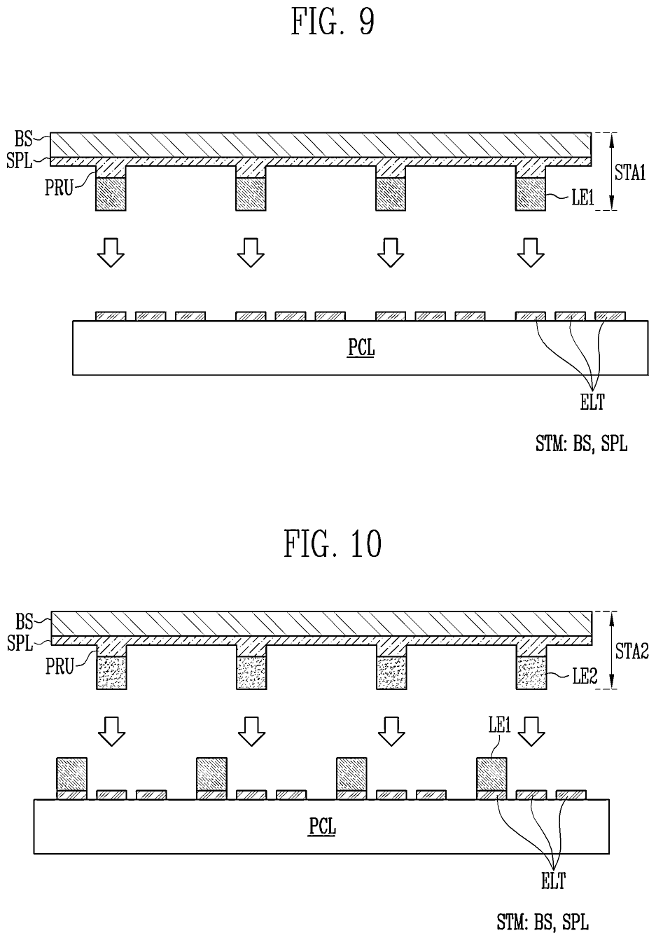

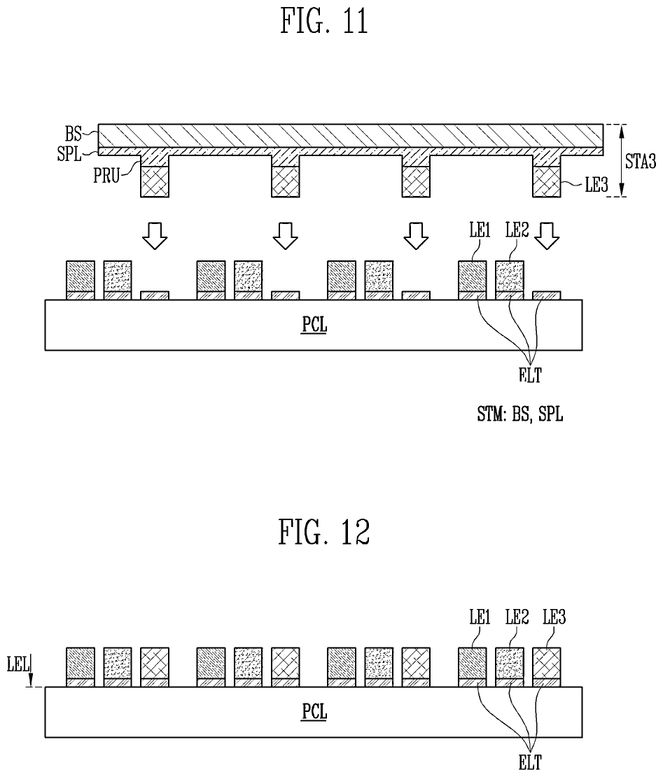

As this step S600 is performed, there may be provided a first stamp assembly STA1 (see FIG. 9) in which the first light emitting element LE1 is disposed on a stamp member STM, a second stamp assembly STA2 (see FIG. 10) in which the second light emitting element LE2 is disposed on a stamp member STM, and a third stamp assembly STA3 (see FIG. 11) in which the third light emitting element LE3 is disposed on a stamp member STM.

Referring to FIGS. 4 and 9 to 13, in the step S800 of transferring the light emitting elements on the pixel circuit layer, each of the first to third light emitting elements LE1 to LE3 may be disposed on the pixel circuit layer PCL.

In this step S800, the pixel circuit layer PCL forming an area in which the light emitting elements LE are transferred may be a panel for providing a single display device 10. By way of example, in an embodiment, the pixel circuit layer PCL is a panel for providing a plurality of display devices 10, and may be a panel separated into individual display devices 10 through a subsequent cutting process.

In this step S800, the pixel circuit layer PCL may be provided, and an electrode layer ELT may be patterned on the pixel circuit layer PCL. The pixel circuit layer PCL may be a layer including a base layer BSL and a pixel circuit PXC, and be manufactured by patterning a conductive layer and an insulating layer on the base layer BSL. In an embodiment, the conductive layer and the insulating layer on the base layer BSL may be manufactured based on an ordinary photolithography process.

In an embodiment, the electrode layer ELT may include a pixel electrode AE and a common electrode CE as described above with reference to FIG. 3. For convenience of description, in drawings from FIG. 9, it is illustrated that a pixel electrode AE and a common electrode CE, which correspond to a light emitting element LE, are included in an electrode layer ELT.

In this step S800, the first stamp assembly STA1 and the pixel circuit layer PCL may be adjacent to each other, and the first light emitting element LE1 may be transferred on the electrode layer ELT at a position at which a first sub-pixel SPX1 is formed (see FIG. 9).

In this step S800, the second stamp assembly STA2 and the pixel circuit layer PCL may be adjacent to each other, and the second light emitting element LE2 may be transferred on the electrode layer ELT at a position at which a second sub-pixel SPX2 is formed (see FIG. 10).

In this step S800, the third stamp assembly STA3 and the pixel circuit layer PCL may be adjacent to each other, and the third light emitting element LE3 may be transferred on the electrode layer ELT at a position at which a third sub-pixel SPX3 is formed (see FIG. 10).

For convenience of description, an embodiment in which the first light emitting element LE1, the second light emitting element LE2, and the third light emitting element LE3 are sequentially transferred is illustrated. However, the disclosure is not limited thereto. The transfer order for each color of the light emitting elements LE may be variously changed.

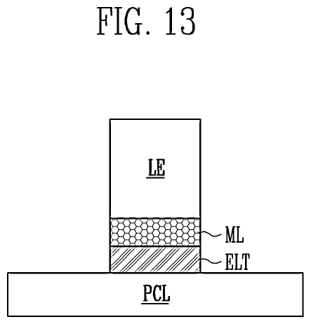

In an embodiment, the light emitting elements LE may be transferred on the pixel circuit layer PCL by various methods. For example, referring to FIG. 13, in case that the light emitting element LE is transferred on the pixel circuit layer PCL, an intermediate layer ML may be disposed on the electrode layer ELT. The intermediate layer ML may include various materials according to the method of transferring the light emitting elements LE. For example, as described above, the intermediate layer ML may be a bump layer. The intermediate layer ML may be a low melting point material layer.

In this step S800, each of the first to third light emitting elements LE1 to LE3 may be disposed on a corresponding electrode layer ELT, to be electrically connected to the electrode layer ELT, and a light emitting element layer LEL may be provided. After that, in an embodiment, additional layers (for example, a window and the like) may be disposed on the light emitting element layer LEL, and the display device 10 in accordance with an embodiment may be manufactured.

In accordance with the disclosure, there can be provided a method of manufacturing a display device and a display device, in which the transfer stability of a light emitting element is ensured and process precision is improved, so that a risk that the light emitting element will not be transferred, and the defect rate of the display device can be decreased.

Example embodiments have been disclosed herein, and although specific terms are employed, they are used and are to be interpreted in a generic and descriptive sense only and not for purpose of limitation. In instances, as would be apparent to one of ordinary skill in the art, features, characteristics, and/or elements described in connection with a given embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure and as set forth in the following claims.

What is claimed is:

1. A method of manufacturing a display device, the method comprising:
manufacturing light emitting elements;
disposing the light emitting elements on a moving member;
bonding the light emitting elements and a stamp member to each other; and
transferring the light emitting elements on a pixel circuit layer, wherein
the moving member includes a moving base and a moving polymer layer on the moving base,
the disposing of the light emitting elements includes attaching the light emitting elements on the moving polymer layer, and
the bonding of the light emitting elements includes separating the light emitting elements and the moving polymer layer from each other by a laser.

2. The method of claim 1, wherein the manufacturing of the light emitting elements includes:
manufacturing a first light emitting element that emits light of a first color;
manufacturing a second light emitting element that emits light of a second color; and
manufacturing a third light emitting element that emits light of a third color.

3. The method of claim 2, wherein
the first light emitting element, the second light emitting element, and the third light emitting element are respectively manufactured on separate growth substrates, and
the manufacturing of the first light emitting element, the manufacturing of the second light emitting element, and the manufacturing of the third light emitting element are sequentially performed.

4. The method of claim 1, wherein the disposing of the light emitting elements includes causing the moving polymer layer and the light emitting elements to contact each other.

5. The method of claim 1, wherein the moving polymer layer includes at least one selected from the group consisting of epoxy resin, phenol resin, polyimide resin, polyurethane resin, melamine resin, and urea resin.

6. The method of claim 1, wherein
the stamp member includes a stamp base and a stamp layer disposed on the stamp base, and
the bonding of the light emitting elements includes the stamp layer and at least some of the light emitting elements contacting each other.

7. The method of claim 6, wherein
the stamp layer includes a plurality of protrusion portions spaced apart from each other, and
the bonding of the light emitting elements includes bonding the light emitting elements respectively to the plurality of protrusion portions.

8. The method of claim 6, wherein the separating of the light emitting elements and the moving polymer layer from each other includes:
applying the laser to at least a portion of the moving polymer layer; and
decreasing an adhesion between the at least a portion of the moving polymer layer, to which the laser is applied, and the light emitting elements.

9. The method of claim 8, wherein, in the separating of the light emitting elements and the moving polymer layer from each other, the adhesion between the at least a portion of the moving polymer layer and the light emitting elements after the laser is applied is less than an adhesion between the stamp layer and the light emitting elements.

10. The method of claim 1, wherein the laser has an ultraviolet wavelength band.

11. The method of claim 10, wherein the laser has a wavelength in a range of about 245 nm to about 350 nm.

12. The method of claim 1, wherein the transferring of the light emitting elements on the pixel circuit layer includes disposing the light emitting elements on the pixel circuit layer by performing a laser bonding process, a thermo-compression bonding process, or a eutectic bonding process.

13. The method of claim 1, wherein each of the light emitting elements is a flip chip type micro light emitting element (LED), a lateral type micro LED, or a vertical type micro LED.

14. A display device manufactured according to the method of claim 1.
